(19) United States
(12) Patent Application Publication
(10) Pub. No.: US 2020/0348354 A1
(43) Pub. Date: Nov. 5, 2020

(54) FOULING SENSOR

(71) Applicant: IJINUS, Mellac (FR)

(72) Inventors: ARNAUD LE GAC, LE TREVOUX (FR); MATHILDE LE NOALLEC, CLEGUER (FR); OLIVIER LE STRAT, QUIMPER (FR); ALBIN MONSOREZ, QUIMPER (FR); YOANN TREGUIER, REDENE (FR)

(21) Appl. No.: 16/861,417

(22) Filed: Apr. 29, 2020

Related U.S. Application Data
(63) Continuation-in-part of application No. 15/737,310, filed on Dec. 17, 2017, now abandoned.

(30) Foreign Application Priority Data
Jun. 18, 2015 (FR) 15 55590

(51) Int. Cl. G01R 31/12; G01R 27/26; G01N 17/00

(52) U.S. Cl. CPC G01R 31/1245; H04B 7/26; G01N 17/008; G01R 27/26

(57) ABSTRACT

A fouling sensor in the form of an electrical insulator including a body. The body includes a dish-shaped portion having a top surface and a bottom surface, and a measurement electrode formed of a printed circuit. Both surfaces are identical and filled with copper. The measurement electrode is positioned inside the dish-shaped portion and the measurement electrode includes an inner surface and an outer surface. The inner surface is oriented towards the inside of the dish-shaped portion and measures the capacitance inside the fouling sensor while the outer surface is grounded. The outer surface is oriented towards the outside of the dish-shaped portion and measures the capacitance outside the fouling sensor while the inner surface is grounded. The body also includes an electrical power supply and a microcontroller configured to instantaneously subtract the capacitive value of the inner surface from that of the outer surface and store the obtained resultant.

### RELATED APPLICATIONS

This application is a continuation-in-part of application Ser. No. 15/737,310 filed Dec. 17, 2017, which is a § 371 application of PCT/FR2016/051480 filed Jun. 17, 2016, which claims priority from French Patent Application No. 15 55590 filed Jun. 18, 2015, each of which is incorporated herein by reference in its entirety

### FIELD OF THE INVENTION

The present invention relates to a fouling sensor for electrical insulators. It applies in particular to the field of the insulators situated between the conductor cables and the supports.

### BACKGROUND OF THE INVENTION

The insulators are subject to the outside environment and cause clogging/pollution of the dishes (glass, ceramic or silicone, etc.). Such is the case on coastal installations or installations close to polluting factories. This pollution causes a build-up of conductive deposits which, under certain humidity conditions, results in current passing over the insulator.

To avoid this problem, costly preventive maintenance of the insulators is carried out on average every six years (installation powered down, cleaning with pressurized distilled water).

The insulators ensure the electrical insulation between the conductor cables and the supports. The insulators are used in a chain, whose length increases with the voltage level.

Approximately the following must be counted:
6 insulators (dishes) at 63 000 volts,
9 at 90 000 volts,
12 at 225 000 volts,
19 at very high voltage of 400 000 volts.

The chain of insulators also serves a mechanical purpose: it has to be capable of withstanding the loads due to the conductors, which are subject to the effects of wind, snow or ice.

As an example, the table below gives the various Very High Voltage (>220 kV) network sizes in different countries:

| | | |
|---|---|---|
| France | 47 000 | km |
| Great Britain | 21 000 | km |
| Germany | 35 000 | km |
| Quebec | 20 000 | km |
| USA | 250 000 | km |

There are very many insulators. In fact, the distance between two VHV (acronym for Very High Voltage) pylons is generally approximately 0.5 km and each comprises insulators on each side of the cable.

The pollution of the insulators constitutes one of the most important factors in energy transport quality and reliability. In effect, in rainy or foggy weather, the polluting deposits (build-up of material) that become fixed onto the insulating surfaces considerably reduce the surface resistivity and flashover can occur.

The moisturization of the polluting layers in fact facilitates the circulation of a leakage current over the insulating surfaces causing local overheating effects and consequently the drying of the layer of pollution. Thus, the distribution of the potential is modified significantly and in some cases partial arcs occur.

The partial arcs can result in a total flashover of the insulator.

The consequences of the flashover range from damage to the surface of the insulator to the decommissioning of the high voltage line.

Thus, one of the main features of a high-voltage insulator is therefore its resistance to flashover as a function of the environment in which it is used.

Pollution has different origins depending on the sites. The pollutions that are of interest here are those which can lead to a flashover:
natural pollution: sea salts in coastal regions, dust from the ground or sand in desert regions. Such pollutions contribute to covering the insulator with more or less conductive deposits which, when they become moist, contribute to the flashover;
industrial pollution: smoke from factories (refineries, cement factories, etc.), exhaust gases, fertilizers used in agricultural, etc., contribute in the same way to the build-up of salts on the surface of the insulator.

The periodicity and the type of servicing of the insulators depend on the pollution rate of the region and on pluviometry. In fact, strong rain will make it possible to wash the surface of the insulators.

The servicing can be carried out by:
periodic manual wiping on the installation powered down,
dry cleaning with the installation live or powered down,
periodic coating with grease,
periodic, high-pressure washing live or powered down.

The economic cost of a current outage ranges from 3 €/kW to 150 €/kW not consumed.

As indicated in the standard IEC TR 60815-1986, the assessment of the severity of the pollution can be performed in three ways:
empirical approach: from an approximate description of the corresponding environment: four levels: low, medium, high, very high;
statistical approach: from information on the behavior of the insulators of lines and substations already in service on the site considered;
metrological approach: from measurements on the site
   volume conductivity of the pollutant harvested by means of direction gages,
   equivalent salt deposit density on the surface (ESDD method: ESDD being the acronym for Equivalent Salt Density Deposit),
   total number of flashovers of chains of insulators of different lengths,
   surface conductance of reference insulators,
   leakage current of insulators subjected to the service voltage.

The aim of the present invention is to limit the maintenance operations by assessing the fouling of the insulators using a reference sensor. Depending on the level of fouling, it is possible to notify a need for maintenance.

### OBJECT AND SUMMARY OF THE INVENTION

The present invention aims to remedy these drawbacks.

To this end, the present invention relates to a fouling sensor in the form of an electrical insulator comprising a body, characterized in that the body comprises:
a dish-shaped part having a top face and a bottom face,
a measurement electrode consisting of a printed circuit whose two faces are identical, and filled with copper. The measurement electrode is positioned inside the dish. The measurement electrode comprises an inner face and an outer face, the inner face is oriented toward the interior of the dish and measures the capacitance internal to the fouling sensor while the outer face is grounded and the outer face is oriented toward the outside of the dish and measures the external capacitance of the fouling sensor while the inner face is grounded,
a microcontroller adapted to instantaneously subtract the capacitive value of the inner face from that of the outer face and store the resultant obtained,
an electrical power supply.

By virtue of these provisions, the fouling sensor for electrical insulators can be a fouling telltale. The fouling sensor accurately indicates the level of conductivity on the outer surface of the dish and does so sustainably over time.

The fouling sensor is a reference sensor intended to be installed in proximity to an element composed of insulators whose fouling needs to be known.

The electrode is a rectangular printed circuit board, called a PCB, whose insulation can be FR-4 (abbreviation for Flame Resistant 4): glass fiber-reinforced epoxy resin composite), its thickness can be 1.6 mm, whose two faces are identically filled with copper. The face oriented toward the interior of the fouling sensor will be called the “inner face”, and the face glued onto the dish, and oriented toward the outside of the sensor, will be called the “outer face”

In one embodiment, the measurement of the internal capacitance or of the external capacitance of the fouling sensor is performed by an electrical measurement by charging each of the faces of the electrode in succession, such as a capacitor, with a direct current for a time.

The electrical measurement by measurement of the dissipation of the electrical charges is understood.

In one embodiment, the sensor comprises a wireless communication board for transmitting data.

In one embodiment, the measurement electrode is fixed under the surface of the top face of the dish. The measurement electrode is positioned inside the dish on the top surface of the dish.

In one embodiment, the measurement electrode is fixed onto the surface of the bottom face of the dish. The measurement electrode is positioned inside the dish on the bottom face of the dish.

In one embodiment, the data sent by the communication board are measurements from the measurement electrode or the data processed by the microcontroller.

In one embodiment, said fouling sensor comprises a temperature sensor and a humidity sensor.

In one embodiment, the measurement electrode is of rectangular form of which the longitudinal axis of the electrode passes through the center of the dish.

In one embodiment, three other measurement electrodes are distributed at 90° relative to one another to form the four cardinal points with the first measurement electrode, such as North, West, South and East.

The installation of the fouling sensor should keep to the positioning of the cardinal points, and be in the same meteorological conditions to which the electrical insulators are subject.

### BRIEF DESCRIPTION OF THE DRAWINGS

Other advantages, aims and features of the present invention will emerge from the following description, given for explanatory purposes and in no way limiting, in light of the attached drawings, in which:

FIGS. 1 to 7 represent diagrams for explaining the operation of the measurement of an electrode in air and in water,

FIG. 8 represents a curve of charging and discharging of an electrode,

FIG. 9 represents a measurement analysis curve,

FIG. 10 represents a cross-sectional view of a fouling sensor for an electrical insulator according to a particular embodiment of the sensor that is the subject of the present invention,

FIG. 11 represents a dish with its four electrodes positioned at the cardinal points according to an exemplary embodiment,

FIG. 12 represents an air benchmark capacitive measurement diagram,

FIG. 13 represents a diagram of the trend of the different daily averages,

FIG. 14 represents a diagram of the different functional components of the fouling sensor,

FIG. 15 represents a diagram of the electrode and microcontroller connected to the inner and outer faces of the electrode according to an exemplary embodiment, and

FIG. 16 represents a diagram illustrating the microcontroller connecting the outer face of the electrode to ground in phase 1 and the inner face of the electrode to ground in phase 2 according to an exemplary embodiment.

### DETAILED DESCRIPTION OF THE EMBODIMENTS

The capacitive technology is based on the electrical characteristics of the capacitor. The capacitor is composed of two conductive foils separated by a substrate. Its characteristic quantity is electrical capacitance, expressed in Farads (F). It reflects the capacity to allow the passage of electrical charges from one foil to the other. The greater the insulation of the substrate separating the two foils, the lower the electrical capacitance.

In the case of the fouling sensor for electrical insulators, a capacitive measurement is done through two capacitances: a capacitance external to the casing and a capacitance internal to the casing.

The capacitor is composed of copper on its two faces of identical shapes and surfaces, hereinafter called the measurement electrode. This measurement electrode is glued inside the dish of the reference sensor.

The outer capacitance (outer face 26) is physically created between the face of the electrode oriented toward the outside of the dish (this is the glued face) and the external medium. This forms the two foils.

An electrical charge V+ is applied to the outer face 26 of the electrode 21. The more conductive the outside medium, the more the electrical charges are dissipated, and therefore the lower the resultant voltage on the face of the electrode (V1) will be. In other words, the higher the dielectric permittivity of the outside medium, the lower the resultant voltage.

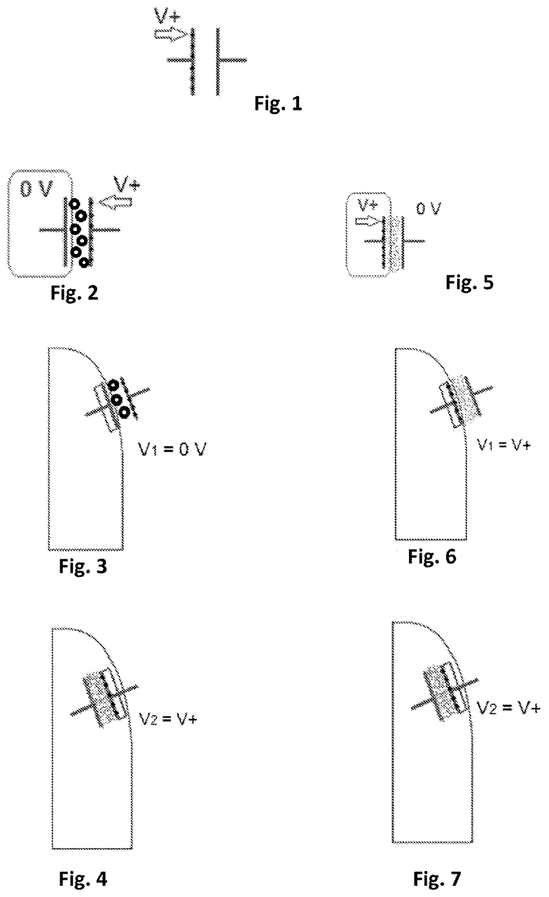

FIGS. 1 to 7 show the measurement operation for an example of a measurement with water and air. If the outside medium is a mass of water, the resultant voltage is zero (dielectric permittivity of water=80). If the outside medium is dry air, the resultant voltage is equivalent to the charge applied V+ (dielectric permittivity of dry air=1, no passage of the electrical charges).

The internal capacitance (inner face 25) is, for its part, created between the face of the electrode oriented toward the interior of the dish and the interior medium. The body (dish shape) is tight to the outside medium. The interior medium is dry air, its only variation is temperature. Similarly, a same charge V+is applied to the face of the electrode, and the resultant voltage is measured (V2). This internal capacitance is important because it makes is possible to provide temperature compensation, and to avoid a measurement drift by having an air reference.

In another exemplary embodiment, the equipment items are “aerated” so as to eliminate the internal/external pressure differences which will create a relative internal humidity content close to that of the outside. This exemplary embodiment makes it possible to show only the influence of the fouling rather than “fouling+humidity content”.

The difference between the two resultant voltages (V2−V1) makes it possible to obtain a reliable and temperature-compensated result. It characterizes the capacity of the polluted surface to conduct electricity.

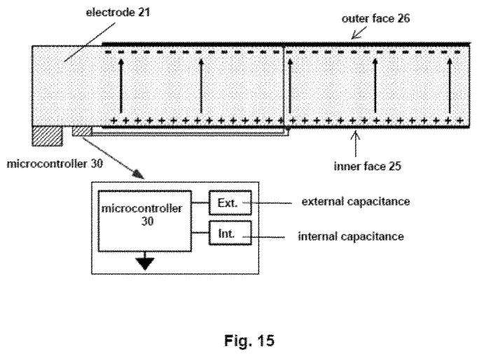

The capacitive measurement is a measurement of electrical type and consists in charging each of the faces of the electrode (inner face 25 and outer face 26) such as a capacitor with a direct current, denoted I, for a time, denoted T (the charging time). As exemplary shown in FIG. 15, the measurement is performed successively by the microcontroller 30, when the inner face 25 of an electrode 21 is measured, the other outer face 26 is grounded.

Before the measurement, the face concerned is grounded, therefore the starting voltage is 0 V to then increase linearly, according to the equation 1, in which C is the capacitance, V the voltage, t the time, I the current:

$$\frac{dV}{dt} = \frac{l}{C} \qquad ( equation 1 )$$

The voltage is then measured at the end of the time T on the face concerned then converted by an analog-digital converter into a numeric value coded on 10 bits. The voltage is inversely proportional to the capacitance, according to the equation 2:

$$V = \frac{l \times T}{C} \qquad ( equation 2 )$$

The measured voltage reflects the dissipation of charges: a zero voltage reflects a high capacitance (the face is in contact with a conductive medium), a high voltage reflects a strong resistivity (the face is in contact with a resistive medium).

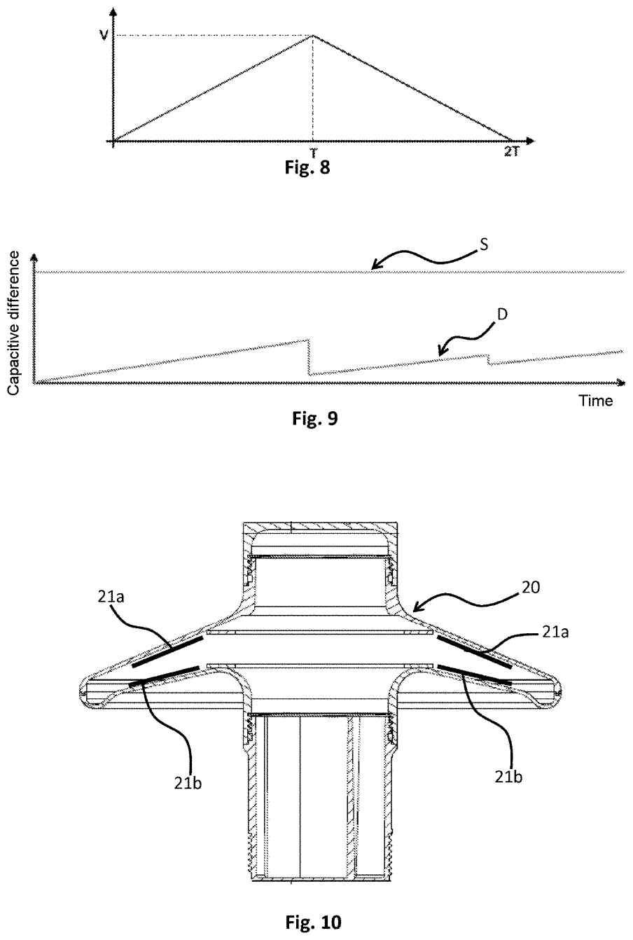

The face concerned is then discharged to the ground, as shown in FIG. 8.

FIG. 8 shows, on the y axis, the voltage V and, on the x axis, the time T. This Figure shows a linear growth to the value T and decreases linearly to 2T.

An example of current and charging time values for the fouling sensor are as follows: I=23 μA and T=2 μs.

In the example represented in the next Figures, the fouling sensor comprises eight measurement electrodes.

The preceding operation is performed consecutively on the eight electrodes present in the fouling sensor. For each of the electrodes 21, the measurement takes place on the inner face 25, then on the outer face 26. When a face 25, 26 is being measured, the other is grounded to form a screen and avoid the dissipation of charges through the latter.

Thus, for each electrode 21, the result thereof is two numerical values: the first reflecting the internal capacitance, the second the external capacitance locally on the electrode.

The microcontroller 30 then performs the subtraction between these two values in order to dispense with all the variables specific to the environment, in particular the temperature.

The value obtained is therefore not temperature-variant, and characterizes the dielectric of the medium on the outer surface of the dish, locally to the electrode. This will be called “capacitive difference”.

Here is an example of calculation of the fouling measurement.

The fouling criterion is calculated over a history of several variables, the recording of which is performed with a regular time step:
meteorological data: temperature, humidity, pluviometry
four North/South/East/West capacitive differences for the bottom face of the dish
four North/South/East/West capacitive differences for the top face of the dish.

The analysis relates to the capacitive differences obtained in dry states of the dish. In effect, the dew and rain make the surface of the dish conductive, placing a ceiling on the capacitive differences, independently of the fouling.

In a variant, the pluviometry of a weather station linked to a recorder. The data are uploaded to a server and the history makes it possible to process the data.

In another variant, the pluviometry linked directly to the fouling sensor by a wireless or wired link depending on the installation.

For that, it is necessary to filter the capacitive differences to keep only those obtained when the measured temperature is sufficiently far from that of the dew point.

The dew point is a thermodynamic datum characterizing the humidity in a gas. The dew point of air is the temperature at which the partial pressure of water vapor is equal to its saturating vapor pressure.

The calculation of the temperature of the dew point is obtained with the following formula, equation 3:

Tr=∛ [symbol] \sqrt{H}·(112+0.9·T)+0.1·T−112 (equation 3)

where T is the measured temperature, H the relative humidity, Tr the dew point temperature.

The fouling criterion consists of a threshold overshoot reached after an upward phase of the eight filtered capacitive differences.

With each rainfall, there can be a more or less pronounced washing of the dish depending on the intensity and the duration of the rainfall, leading to a modeling of the filtered capacitive differences in saw tooth form as follows, see FIG. 9):

FIG. 9 shows a fouling threshold, denoted S. The fouling threshold is horizontal linear. The curve of the capacitive difference, denoted D, is in saw tooth form and the vertical parts correspond to the rain. The amplitude depends on the intensity and the duration of the rainfall.

This upward phase is perceptible with different time scales: several days, several months, several years depending on the pollution level. In another example, there is no upward phase if the pollution is minimal, or frequent rainfall provides regular washing.

Coupled with the meteorological and hygrometric data, the history of the measurements makes it possible to assess the level of fouling of the insulators. These data are stored in meteorological recorders (weather station).

The fouling sensor in the form of an insulator is a reference solution, which means that it has a behavior that is as close as possible to the electrical insulator observed—both by its geometry and the behavior of its material.

The electrical insulators constitute chains when several insulators are positioned in succession one behind the other.

In the chain of dishes that the insulator forms, the dishes are not fouled in the same way.

For the vertically-positioned electrical insulators, the face situated uppermost is exposed to the rainwater which will make it possible to wash it with each heavy rainfall, whereas the lowest face is the one least washed because it is not washed by the rainfall, or washed by the bouncing of the rain on the bottom face of the dish.

These two faces are therefore representative respectively of the heaviest and the weakest pollution.

If the fouling sensor is composed of a single dish, it will make it possible to have the minimum and maximum fouling of the insulator chain. The profile is that of a standard VHV (Very High Voltage) insulator, see FIG. 10.

In the exemplary embodiment that can be seen in FIG. 10, the fouling sensor has a top face and a bottom face. Two measurement electrodes 21a are represented and fixed, inside the dish, on the surface of the top face of the dish 20. Two measurement electrodes 21b are represented and fixed inside the dish, on the surface of the bottom face of the dish 20. The connecting wires of the electrodes are not represented.

The material on the fouling sensor is PPS (PolyPhenylene Sulfide).

This material meets the following criteria:
dielectric constant that is sufficient to allow the measurement,
resistance to UV (ultraviolet), very small surface roughness, hydrophobic, antistatic,
not permeable to water vapor,
high chemical resistance,
great dimensional stability over a wide temperature range from −40° to +100° C.

In an exemplary embodiment, the fouling sensor is tight to IP65 (resistant to bad weather).

In another exemplary embodiment and given the exposure of the fouling sensor, it is preferable to certify a protection level of IP67 (Index of Protection 67) (30 min under 1 m of water).

The fouling sensor comprises various components:
a mother board: management of the daughter boards and mathematical operations incorporating a microcontroller 30, a memory, a first short-range radio frequency channel for configuration;
a communication board: transmission of the data by a second radio frequency cellular communication channel (GSM (Global System for Mobiles), GPRS (General Packet Radio Service) for mobile telephony, 3G for third generation, 4G for fourth generation, etc.) or long-range low bit rate communication networks;
a measurement board: measuring the difference in capacitance between the internal electrodes and the external electrodes glued to the body, the humidity and the temperature;
electrode boards: the measurement electrodes incorporating the electronic conversion component which is directly placed at the foot of the electrode to minimize the influence of the link between the component and the electrodes, in effect, the length of the wires disrupts the measurement through resistivity, the capacitance of the line and the electromagnetic disturbances.

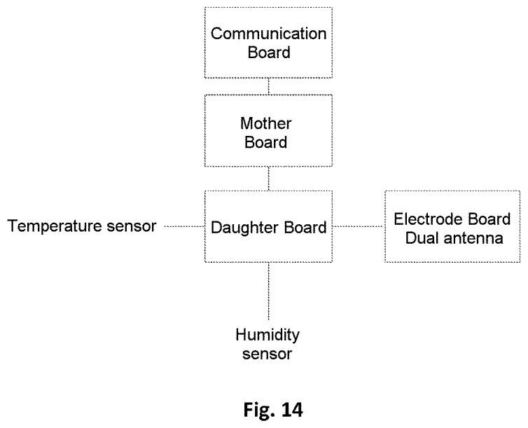

See FIG. 14 which shows a diagram of an embodiment.

Since the pollution is borne by the wind and/or the rain, this pollution will not therefore be uniformly distributed over the surface or surfaces of the fouling sensor.

The measurement principle for detecting a pollution of the insulators makes it possible to detect its cardinal origin and makes it possible to consolidate the measurement.

For that, the fouling sensor consists of three other measurement electrodes positioned inside the dish. A first network of measurement electrodes is situated at least on the four cardinal points, North, West, South, East, on the top surface of the dish of the fouling sensor.

In another exemplary embodiment, a second network of measurement electrodes is situated at least on the four cardinal points, North, West, South, East, on top of the bottom surface of the insulator and inside the dish. In this version, the second network of measurement electrodes is situated on the bottom surface of the dish of the fouling sensor.

These two networks are perfectly identical and located in the same axis in order to be able to compare the measurements of the top network to the bottom network.

In another example, the sensor comprises both fouling networks:

The fouling sensor comprises eight measurement electrodes positioned inside the dish, of which four electrodes are situated at the four cardinal points, North, West, South, East, on the top surface of the dish of the fouling sensor and four other measurement electrodes are situated at the four cardinal points, North, West, South, East, on the bottom surface of the dish of the fouling sensor. The eight measurement electrodes are inside the dish and therefore the fouling sensor.

The measurement principle in this case is as follows:

1. comparative capacitive measurement of the two faces: external capacitance (outer face 26) to the internal capacitance (inner face 25) for each measurement electrode 21 of the top network determining the level of pollution of the top dish.

2. comparative capacitive measurement of the two faces: external capacitance (outer face 26) to the internal capacitance (inner face 26) for each measurement electrode of the bottom network determining the level of pollution of the bottom dish.

3. determination of the capacitive differences by comparison between each measurement electrode of the top network validating the level of pollution and determining a cardinal origin of the pollution.

4. determination of the capacitive differences by comparison between each measurement electrode of the bottom network validating the level of pollution and determining a cardinal origin of the pollution.

5. comparative measurement between the top network of measurement electrodes and the bottom network of measurement electrodes determining the cardinal origin of the pollution validating the cardinal origin of the pollution.

6. if necessary, comparative measurement between a communicating and synchronized network of fouling sensors.

These six steps are exemplary embodiments and can be taken independently of one another.

In an exemplary embodiment, the invention relates to a method implementing the fouling sensor for electrical insulators as described previously in the context of the invention and comprising the steps of:
a) collecting the capacitive value of the inner face 25 of the measurement electrode 21 at an instant t, while the outer face 26 is linked to the ground;
b) collecting the capacitive value of the outer face 26 of the measurement electrode 21 at the instant t while the inner face 25 is linked to the ground; and
c) subtracting the two values collected at the instant t to obtain a subtracted value.

The subtracted value is independent of the temperature.

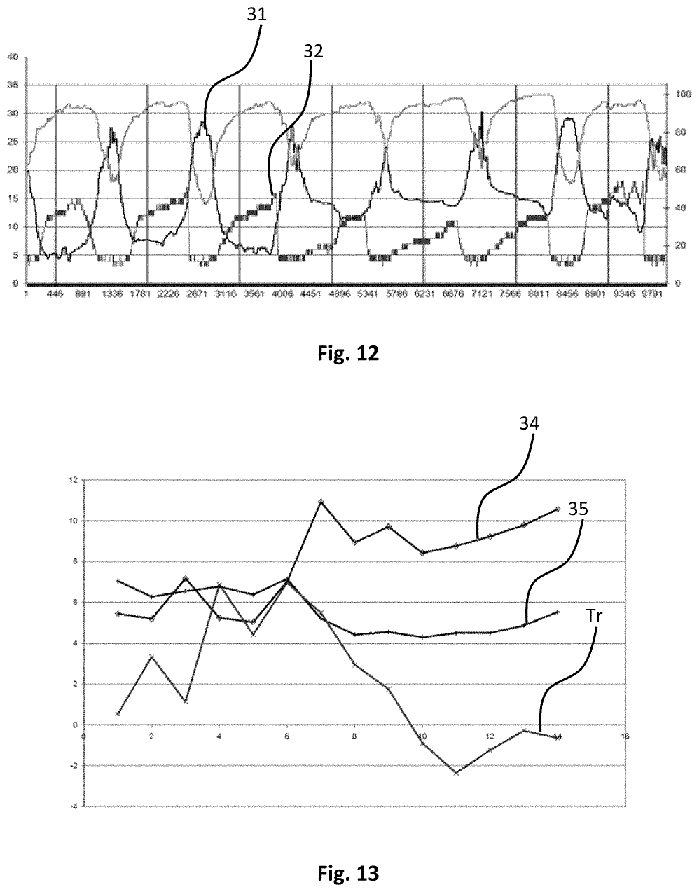

FIG. 12 represents an air benchmark capacitive measurement scheme.

Experimentation has consisted in placing the fouling sensor in an outside medium, in an environment not subject significantly to pollution, and in recording, over a week, with a time interval of one minute, the temperature (curve 31, in ° C.), the relative humidity (curve 33, in % RH), and the capacitive difference of a representative electrode (curve 32, without unit).

The measurements of the Figure clearly demonstrate the stability of the air benchmark capacitive measurement, not dependent on temperature and dependent on the dew cycles. The cycle shows the repeatability of the capacitive measurement between 4 and 17 on the y axis on the left, (x axis being the time) and the y axis on the right being the humidity.

The grid represents the daily period, the curve 31 represents the curve of measured temperature in degrees Celsius, the curve 32 represents the curve of capacitive value measured on a fouling sensor, the curve 33 represents the curve of measured humidity.

Two identical fouling sensors are placed in the same conditions for several weeks. Their measurements are identical and vary as a function of the humidity.

In FIG. 13, the curve of humidity and of temperature are synthesized under the parameter Tr.

Tᵣ=∛\sqrt{H}·[112+(0.9·T)]+(0.1·T)−112
Tr, dew point in ° C.
T, temperature in ° C.
H, relative humidity in %.

The trial consisted in placing two fouling sensors in the same conditions, in an outside medium, in an environment not subject significantly to pollution. It then involved recording, over two weeks, with the time interval of one minute, the temperature, the relative humidity, and the capacitive difference of a representative electrode for each sensor. At the end of six days of testing, one of the two sensors was fouled with seawater by spraying (curve of the fouling sensor 34), the other was subjected to the same spraying but with distilled water (curve of the fouling sensor 35).

The graph synthesizes, the form of daily averages, the temperature of the dew point (in ° C., calculated from the temperature and the relative humidity), and the capacitive difference representative of each sensor.

The graph shows the trend of the different daily averages. This Figure makes it possible to see that the measurement principle does indeed address a fouling (dielectric).

FIG. 14 represents a diagram of the different functional components of the fouling sensor.

In this example, the communication board transmits information remotely. The mother board comprises the management of the daughter board and the mathematical functions incorporating a microcontroller 30, and the radio 1. The radio 1 is a proprietary protocol called WIJI® (registered trademark) (frequency of 868 Mhz for Europe, 915 Mhz for the United States), used for configuration and any updates of the sensors, for recovering data locally and for exchanges of data between sensors if necessary.

The communication board comprises the radio 2, the transmission of the data by a second radio frequency channel. The second channel makes it possible to upload the data to a server.

The communication board uses at least one of the following modalities: radio waves, for example UHF (acronym for Ultra High Frequency), lightwaves, for example infrared, soundwaves, for example infrasound or ultrasound and/or communication specifications on a radio frequency network, for example SIGFOX (registered trademark), LORA (registered trademark), GSM/GPRS (registered trademark).

The electrode board corresponds to a measurement electrode explained hereinabove.

The daughter board is a serial interface between the mother board, the network of electrode boards and the humidity and temperature sensors.

In accordance with an exemplary embodiment of the claimed invention, the capacity measurements using the fouling sensor comprising eight measurement electrodes 21 are described herein. The fouling detection system operates by utilizing a control insulator (fouling sensor) containing instrumentation for quantifying different physical quantities:
Temperature,
Humidity,
Surface conductivity is measured in 8 points (8 measuring electrodes) according to a capacitive method.

In accordance with an exemplary embodiment of the claimed invention, the eight electrodes 21 are glued on the inner surfaces of a case (FIG. 10 is an example showing four electrodes):
four electrodes 21a in upper position (e.g., inside a dish glued to the outer face thereof); and
four electrodes 21b in the lower position (inside a cup glued to the inner face thereof).

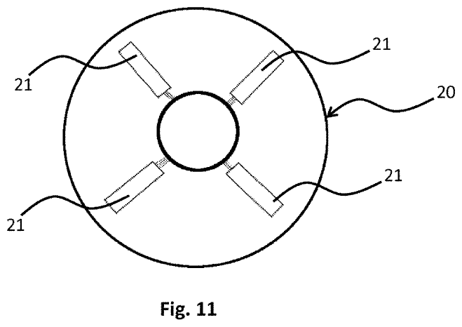

In accordance with an exemplary embodiment of the claimed invention, FIG. 11 shows the inside of the fouling detection device (fouling sensor). The electrodes are clearly visible at 90° from each other on the face.

In accordance with exemplary embodiment of the claimed invention, FIG. 15 depicts one of the electrodes 21, a component enabling the measurement of surface conductivity by capacitive effect is directly implanted therein. The electrodes are all connected to a mother board by a digital bus.

The purpose of these eight electrodes 21 is to quantify the surface conductivity of the control insulator by comparing the flow of charges to the outside and the inside of the body. A so-called “capacitive measurement method” is employed in the way that each of the electrodes 21 is successively excited by a constant current for a certain duration and the resulting voltage is then measured. The greater the flow of the charges, the lower the resulting tension at the end of the excitation and vice versa.

The eight electrodes 21 are identical. Each electrode 21 is composed of a printed circuit incorporating a measurement circuit and two similar copper surfaces positioned on each of the faces of the printed circuit. An exemplary electrode 21 is shown in FIG. 15.

The process is identical for each of the eight electrodes 21, the quantification of the surface conductivity is performed in two phases by the microcontroller 30:
1) Connection to the ground of the outer face 26 and excitation of the inner face 25 with a defined torque “current/time”, then measurement of the resulting voltage on the inner face 25.
2) Connection to the ground of the inner face 25 and excitation of the outer face 26 with the same torque “current/time”, then measurement of the resulting voltage on the outer face 26.

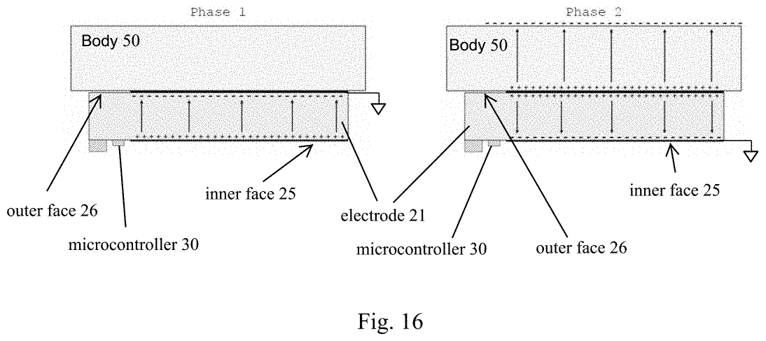

As exemplary shown in FIG. 15, the microcontroller 30 is connected to the outer face 26 and the inner face 25 of the electrode 21 and connects one of the inner and outer faces to a voltage and the other face to the ground. As exemplary shown in FIG. 16, the process in the 2 phases is as follows:
Phase 1: The microcontroller 30 connects the outer face 26 of the electrode 21 to ground. The transfer of charges is only performed from the inside to the outer face 26 of the electrode 21 which is a screen between the inner excited inner face 25 of the electrode 21 and the outside of the body 50.
Phase 2: The microcontroller 30 connects the inner face 25 of the electrode 21 to ground. Charge transfer is also performed from one face to the other but also between the excited outer face 26 of the electrode 21 and the outer surface of the body 50.

The microcontroller 30 changes the connection of either the inner face 25 or the outer face 26 to the ground during the phase change, e.g., the microcontroller 30 switches the ground connection from the outer face 26 to the inner face 25 during the phase change from 1 to 2, and vice-versa during the phase change from 2 to 1.

The difference measured between the two phases is therefore representative of the surface conductivity of the body, it is the evolution of this information, which allows to highlight an indicator on the level of fouling of the control insulator.

The claimed invention, having been described, will make apparent to those skilled in the art that the same may be varied in many ways without departing from the spirit and scope of the invention. Any and all such modifications are intended to be included within the scope of the following claims.

1. A fouling sensor in the form of an electrical insulator comprising a body, the body comprising:
a dish-shaped part comprising a top face and a bottom face;
a measurement unit consisting of a printed circuit comprising a top face and a bottom face that are identical and filled with copper, the measurement unit is positioned inside the dish-shaped part, the measurement unit comprises an inner face and an outer face, the inner face is oriented toward an interior unit of the dish-shaped part and is configured to measure an internal capacitance of the fouling sensor while the outer face is grounded, and the outer face is oriented toward the outside of the dish-shaped part and is configured to measure an external capacitance of the fouling sensor while the inner face is grounded;
a microcontroller configured to connect the outer face to the ground during the internal capacitance measurement, to connect the inner face to the ground during the external capacitance measurement and to instantaneously subtract a capacitive value of the inner face from that of the outer face and to store an obtained resultant voltage; and
an electrical power supply.

2. The fouling sensor as claimed in claim 1, wherein the measurement of the internal capacitance or the external capacitance is performed by an electrical measurement by charging each of the inner and outer faces of the measurement unit in succession with a direct current for a predetermined time.

3. The fouling sensor as claimed in claim 2, wherein the measurement unit is a capacitor.

4. The fouling sensor as claimed in claim 1, further comprising a wireless communication board configured to transmit data.

5. The fouling sensor as claimed in claim 1, wherein the measurement unit is fixed under a surface of the top face of the dish-shaped part.

6. The fouling sensor as claimed in claim 1, wherein the measurement unit is fixed on a surface of the bottom face of the dish.

7. The fouling sensor as claimed in claim 2, further comprising a wireless communication board configured to transmit data; and wherein the data sent by the wireless communication board are the measurements from the measurement unit or the data processed by the microcontroller.

8. The fouling sensor as claimed in claim 1, further comprising a temperature sensor and a humidity sensor.

9. The fouling sensor as claimed in claim 1, wherein the measurement unit is of a rectangular form in which a longitudinal axis of the measurement unit passes through a center of the dish-shaped part.

10. The fouling sensor as claimed in claim 1, further comprising four measurement units distributed at 90° relative to one another to form four cardinal points, such as North, West, South and East.
